(19) United States
(12) Patent Application Publication
(10) Pub. No.: US 2015/0279705 A1
(43) Pub. Date: Oct. 1, 2015

(54) Microwave Heating Method and Microwave Heating Apparatus

(71) Applicant: TOKYO ELECTRON LIMITED, Tokyo (JP)

(72) Inventor: Takaaki IWAI, Nirasaki City (JP)

(21) Appl. No.: 14/656,164

(22) Filed: Mar. 12, 2015

(30) Foreign Application Priority Data
Mar. 25, 2014 (JP) 2014062326

(51) Int. Cl. H01L 21/67; H01L 21/321; H05B 6/64; H01L 21/324

(52) U.S. Cl. CPC H01L 21/67115; H01L 21/324; H01L 21/321; H05B 6/645

(57) ABSTRACT

A microwave heating method includes: heating an object to be treated by irradiation of microwaves onto the object to be treated, the object to be treated having a film to be annealed and a substrate body on which the film to be annealed is formed; and stopping the irradiation of the microwaves, wherein the film to be annealed has a temperature rising rate by the irradiation of the microwaves higher than that of the substrate body. Switching from the heating the object to be treated to the stopping the irradiation of the microwaves is performed, after a temperature T₁ of the film to be annealed reaches a temperature equal to or greater than a target temperature T of the film to be annealed by the irradiation of the microwaves, and before a temperature T₂ of the substrate body reaches a steady state.

### CROSS-REFERENCE TO RELATED APPLICATION

This application claims the benefit of Japanese Patent Application No. 2014-062326, filed on Mar. 25, 2014, in the Japan Patent Office, the disclosure of which is incorporated herein in its entirety by reference.

### TECHNICAL FIELD

The present disclosure relates to a microwave heating method and a microwave heating apparatus, in which microwaves are introduced into a treatment container to heat a substrate.

### BACKGROUND

A metal such as an aluminum alloy, tungsten or copper is used as a wiring material, or an embedded material for a contact hole in a semiconductor device. When the metal is used, a barrier layer is interposed at an interface between a film made of the metal and an insulating film or an underlying conductive film. The barrier layer is formed to prevent diffusion into the insulating film, improve close contact between the films, reduce resistance in contact with the conductive film, and the like. For example, Ta, TaN, Ti, TiN or the like is used as a material for the barrier layer. Also, it is known that the barrier layer is silicided, thereby reducing electrical resistance. In order to sufficiently promote a silicidation reaction of the barrier layer, there has been proposed a film forming method in which a metal film including Ti is formed using a plasma CVD technique and then an annealing treatment is performed on the metal film.

It has been known that an apparatus using microwaves is employed as an apparatus for performing an annealing treatment on a substrate such as a semiconductor wafer. The annealing treatment with microwaves has many advantages in processes in that it enables interior heating, local heating and selectable heating, as compared with an annealing apparatus using a conventional lamp heating or resistance heating technique. For example, when the annealing treatment of a metal film is performed using microwave heating, it is considered that microwaves act directly on the metal film, so that surplus heating does not occur and the annealing treatment can be performed at a relatively lower temperature as compared with a conventional lamp heating or resistance heating technique, thereby suppressing an increase in thermal budget.

When the annealing treatment is performed on a substrate, the temperature of the substrate is usually measured by a pyrometer installed at a back side (generally, a lower side) of the substrate. The pyrometer senses heat radiation, thereby measuring a surface temperature of an object to be measured in a non-contact manner. Accordingly, the surface temperature at the back side of the substrate is measured directly by the pyrometer. Since various kinds of semiconductor devices are fabricated on a front side (generally, an upper side) of the substrate, however, a film to be subjected to an annealing treatment (a film to be annealed) exists on the front side (which is not limited to an uppermost surface) of the substrate. For this reason, the pyrometer cannot directly measure the temperature of the film to be annealed, so that the pyrometer may measure the surface temperature of the back side of the substrate so as to indirectly catch the temperature of the film to be annealed from the measured result.

As described above, an annealing treatment with microwave irradiation has advantages in that it enables interior heating, local heating and selectable heating. If a film to be annealed is made of a material having a microwave-heated temperature-rising rate higher than that of a substrate body, the temperature of the film in an initial stage of the annealing treatment is raised by means of selective heating. In the next stage, the temperature of the substrate body is gradually raised by means of heat conduction from the film in addition to the microwave irradiation. Finally, the film to be annealed and the substrate body are considered to reach thermal equilibrium so that a temperature difference will be almost constant.

In a conventional annealing apparatus, however, the surface temperature of the back side of the substrate body is measured, and the end point of the annealing treatment is determined based on the measured temperature. Further, in order to ensure the annealing treatment, microwaves continue to irradiate until the surface temperature of the back side of the substrate body reaches a steady state, and the end point of the annealing treatment is then determined. Therefore, heating has been performed actually at a higher temperature and/or for an unnecessarily longer time on the film to be annealed, rather than a minimum heating temperature and heating time required for the annealing treatment. As a result, the advantage of the microwave irradiation cannot be sufficiently exhibited. As such, in the conventional annealing treatment using microwaves, it is not possible to completely dissolve problems of reduced throughput or increased power consumption due to microwave irradiation for an unnecessarily long time, or to dispel a risk of increased thermal budget for the entire substrate.

### SUMMARY

Some embodiments of the present disclosure provide a microwave heating method and a microwave heating apparatus, in which harmful effects caused by excessive microwave irradiation can be suppressed while efficiently performing annealing treatment on a film to be annealed for a short time.

According to an embodiment of the present disclosure, there is provided a microwave heating method including: heating an object to be treated by irradiation of microwaves onto the object to be treated, the object to be treated having a film to be annealed and a substrate body on which the film to be annealed is formed; and stopping the irradiation of the microwaves, wherein the film to be annealed has a temperature rising rate by the irradiation of the microwaves higher than that of the substrate body. Switching from the heating the object to be treated to the stopping the irradiation of the microwaves is performed, after a temperature T₁ of the film to be annealed reaches a temperature equal to or greater than a target temperature T of the film to be annealed by the irradiation of the microwaves, and before a temperature T₂ of the substrate body reaches a steady state.

According to another embodiment of the present disclosure, there is provided a microwave heating apparatus including: a treatment container that has a microwave radiation space and accommodates an object to be treated; a supporting device that supports the object to be treated in the treatment container; a microwave introduction device that generates microwaves for heating the object to be treated and introduces the generated microwaves into the treatment container; a temperature-measuring device that measures a temperature of the object to be treated; and a control unit that controls irradiation of the microwaves onto the object to be treated, wherein the object to be treated has a film to be annealed and a substrate body on which the film to be annealed is formed. If the film to be annealed has a temperature rising rate by the irradiation of the microwaves higher than that of the substrate body, the control unit performs switching from heating the object to be treated by irradiation of the microwaves to stopping the irradiation of the microwaves, after a temperature T₁ of the film to be annealed reaches a temperature equal to or greater than a target temperature T of the film to be annealed by the irradiation of the microwaves, and before a temperature T₂ of the substrate body reaches a steady state.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a sectional view showing a schematic configuration of a microwave heating apparatus according to an embodiment of the present disclosure;

FIG. 2 is a plan view showing a lower surface of a ceiling portion of a treatment container shown in FIG. 1;

FIG. 3 is an explanatory view illustrating a schematic configuration of a high-voltage power supply unit of the microwave heating apparatus shown in FIG. 1;

FIG. 4 is a block diagram illustrating a hardware configuration of a control unit;

FIG. 5 is a schematic view showing a sectional structure of an example of a semiconductor wafer that is an object to be treated;

FIG. 6 is a schematic view showing a state in which a metal silicide layer is formed by performing an annealing treatment on the semiconductor wafer shown in FIG. 5;

FIG. 7 is a schematic view showing a sectional structure of another example of the semiconductor wafer that is an object to be treated;

FIG. 8 is a schematic view showing a sectional structure of a further example of the semiconductor wafer that is an object to be treated;

FIG. 9 is a graph showing an example of temperature rising behaviors of a film to be annealed and a substrate body when heating is performed by microwave irradiation;

FIG. 10 is a graph showing another example of temperature rising behaviors of the film to be annealed and the substrate body when heating is performed by microwave irradiation;

FIG. 11 is a graph showing a temperature difference ΔT between the film to be annealed and the substrate body when the film thickness of the film to be annealed is changed;

FIG. 12 is a graph showing a relationship of the temperature difference ΔT between the film to be annealed and the substrate body with the film thickness of the film to be annealed;

FIG. 13 is a graph showing a change in the temperature of the substrate body when annealing treatment is performed on the film to be annealed while changing microwave power;

FIG. 14 is a graph showing the temperature difference ΔT between the film to be annealed and the substrate body when an annealing treatment is performed on the film to be annealed while changing microwave power;

FIG. 15 is a view showing an example of a table in which switching timings from a first step to a second step are recorded; and

FIG. 16 is a graph showing a formation curve of Ti silicide by annealing treatment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

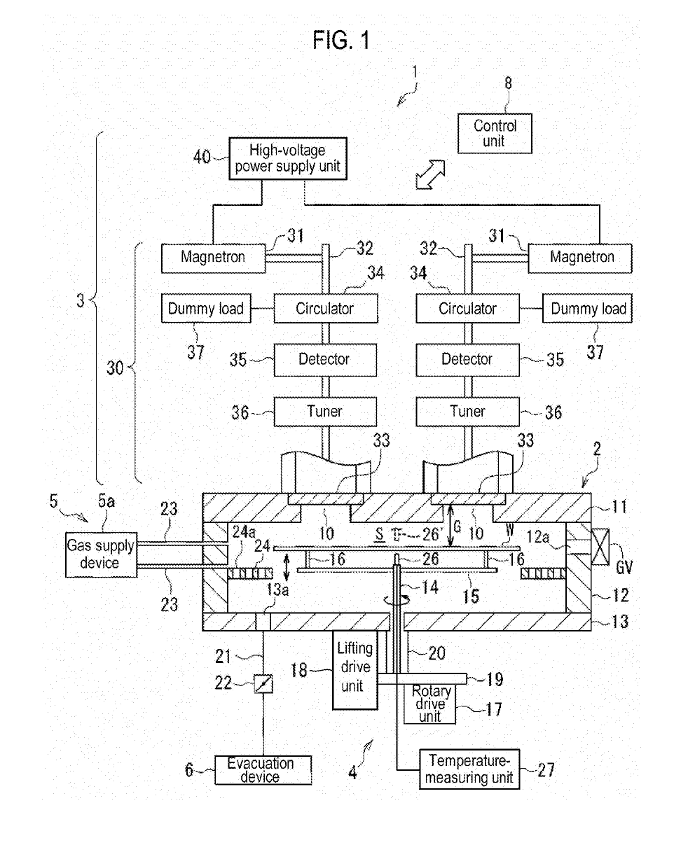

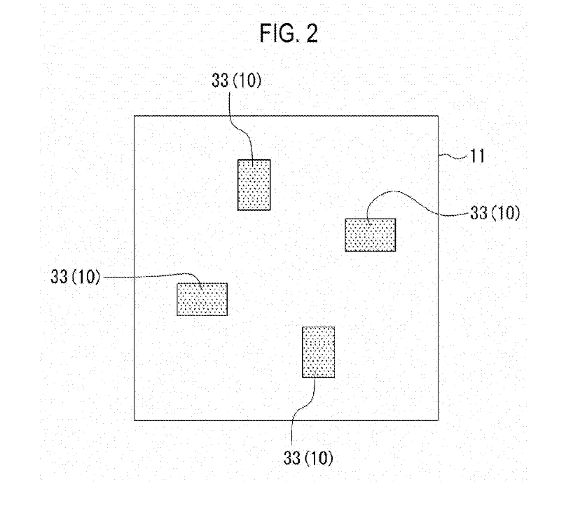

First, a microwave heating apparatus according to an embodiment of the present disclosure will be described with reference to FIG. 1. FIG. 1 is a sectional view showing a schematic configuration of a microwave heating apparatus. FIG. 2 is a plan view showing a lower surface of a ceiling portion of a treatment container shown in FIG. 1. The microwave heating apparatus 1 is an apparatus for performing an annealing treatment by involving a plurality of consecutive operations, e.g., by irradiating microwaves onto a semiconductor wafer (hereinafter, simply referred to as a ‘wafer’) W for fabrication of a semiconductor device.

The microwave heating apparatus 1 includes a treatment container 2 for accommodating the wafer W that is an object to be treated, a microwave introduction device 3 for introducing microwaves into the treatment container 2, a supporting device for supporting the wafer W in the treatment container 2, a gas supply mechanism 5 for supplying gases into the treatment container 2, an evacuation device 6 for depressurizing and evacuating the interior of the treatment container 2, and a control unit 8 for controlling respective components of the microwave heating apparatus 1.

### <Treatment Container>

The treatment container 2 is formed of a metallic material. For example, aluminum, an aluminum alloy, stainless steel, or the like is used as the material for forming the treatment container 2. The microwave introduction device 3 is mounted at the top of the treatment container 2, and functions as a microwave introduction means for introducing electromagnetic waves (microwaves) into the treatment container 2. The configuration of the microwave introduction device 3 will be described in detail later.

The treatment container 2 has a plate-shaped ceiling portion 11 as a top wall, a bottom portion 13 as a bottom wall, four side wall portions 12 as side walls for connecting the ceiling portion 11 and the bottom portion 13, a plurality of microwave introduction ports 10 provided to vertically pass through the ceiling portion 11, a loading/unloading port 12a provided in the side wall portion 12, and an exhaust port 13a provided in the bottom portion 13. Here, the four side wall portions 12 define the shape of a rectangular tub in which they are connected perpendicular to one another when viewed in cross section. Thus, the treatment container 2 defines a cubic shape of which interior is hollow. An inner surface of each of the side wall portions 12 is entirely flat, and has a function as a reflective surface for reflecting microwaves. The loading/unloading port 12a is used to perform loading and unloading of the wafer W between the treatment container 2 and a conveyance chamber (not shown) adjacent to the treatment container 2. A gate valve GV is installed between the treatment container 2 and the conveyance chamber (not shown). The gate valve GV has a function of opening and closing the loading/unloading port 12a, and tightly seals the treatment container 2 in the closed state while enabling the wafer W to be transferred between the treatment container 2 and the conveyance chamber (not shown) in the opened state.

### <Supporting Device>

The supporting device 4 has a tubular shaft 14 passing through nearly the center of the bottom portion 13 of the treatment container 2 and extending to the outside of the treatment container 2, a plurality of (e.g., three) arm portions 15 mounted in a generally horizontal direction from an upper end of the shaft 14, a plurality of support pins 16 detachably mounted on the respective arm portions 15, a rotary drive unit 17 for rotating the shaft 14, a lifting drive unit 18 for vertically displacing the shaft 14, and a movable connection portion 19 for supporting the shaft 14 and simultaneously connecting the rotary drive unit 17 and the lifting drive unit 18. The rotary drive unit 17, the lifting drive unit 18 and the movable connection portion 19 are installed outside of the treatment container 2. When the interior of the treatment container 2 is in a vacuum state, a seal mechanism 20 such as a bellows may be installed around a portion where the shaft 14 passes through the bottom portion 13.

In the supporting device 4, the shaft 14, the arm portion 15, the rotary drive unit 17 and the movable connection portion 19 constitute a rotation mechanism for horizontally rotating the wafer W supported by the support pins 16. In the supporting device 4, the shaft 14, the arm portion 15, the lifting drive unit 18 and the movable connection portion 19 also constitute a height adjustment mechanism for adjusting the height of the wafer W supported by the support pins 16. The plurality of support pins 16 are brought into contact with and support a back side of the wafer W within the treatment container 2. The plurality of support pins 16 is disposed such that their upper ends are arranged in a circumferential direction of the wafer W. The plurality of arm portions 15 rotate about the shaft 14 by actuating the rotary drive unit 17, and cause the respective support pins 16 to revolve in a horizontal direction. Further, the plurality of support pins 16 and arm portions 15 are also configured to be displaced vertically in a lifted and lowered manner together with the shaft 14 by actuating the lifting drive unit 18.

The plurality of support pins 16 and arm portions 15 are formed by a dielectric material. For example, quartz, ceramic or the like may be used as the material for forming the plurality of support pins 16 and arm portions 15.

The rotary drive unit 17, which is not particularly limited so long as it can rotate the shaft 14, may have, for example, a motor (not shown) or the like. The lifting drive unit 18, which is not particularly limited so long as it can displace the shaft 14 and the movable connection portion 19 in the lifted and lowered manner, may have, for example, a ball screw (not shown) or the like. The rotary drive unit 17 and the lifting drive unit 18 may be an integrated mechanism, and may have a configuration without the movable connection portion 19. Further, the rotation mechanism for horizontally rotating the wafer W and the height adjustment mechanism for adjusting the height of the wafer W may have different configurations so long as they can achieve their purposes.

### <Evacuation Device>

The evacuation device 6 has a vacuum pump such as a dry pump. The microwave heating apparatus 1 further includes an exhaust pipe 21 for connecting the exhaust port 13a and the evacuation device 6, and a pressure regulation valve 22 installed along the path of the exhaust pipe 21. The vacuum pump of the evacuation device 6 is operated so that the internal space of the treatment container 2 is depressurized and evacuated. Further, the microwave heating apparatus 1 can also perform treatment at atmospheric pressure where the vacuum pump is not required. Instead of using the vacuum pump such as a dry pump as the evacuation device 6, any evacuation equipment installed in a facility provided with the microwave heating apparatus 1 may be used.

### <Gas Introduction Mechanism>

The microwave heating apparatus 1 further includes the gas supply mechanism 5 for supplying gases into the treatment container 2. The gas supply mechanism 5 has a gas supply device 5a provided with a gas supply source (not shown), and a plurality of pipes 23 (only two of them are shown) connected to the gas supply device 5a so as to introduce process gases into the treatment container 2. The plurality of pipes 23 are connected to the side wall portion 12 of the treatment container 2.

The gas supply device 5a is configured to supply, through the plurality of pipes 23, gases such as N₂, Ar, He, Ne, O₂, H₂ and the like as the process gases into the treatment container 2 in a side flow manner. Further, the supply of the gases into the treatment container 2 may be performed, for example, by mounting a gas supply means at a position opposite to the wafer W (e.g., on the ceiling portion 11). Further, instead of the gas supply device 5a, an external gas supply device that is not included in the configuration of the microwave heating apparatus 1 may also be used. Although not shown, the microwave heating apparatus 1 further includes a mass flow controller and an opening/closing valve, installed along the paths of the pipes 23. The kinds of gases supplied into the treatment container 2, the flow rates of the gases, and the like are controlled by the mass flow controller and the opening/closing valve.

### <Flow-Conditioning Plate>

The microwave heating apparatus 1 further includes a flow-conditioning pate 24 in the form of a frame between the side wall portions 12 and around the plurality of support pins 16 within the treatment container 2. The flow-conditioning plate 24 has a plurality of flow-conditioning holes 24a formed to vertically pass through the flow-conditioning plate 24. The flow-conditioning plate 24 is used to condition the atmosphere of a region where the wafer W is to be disposed within the treatment container 2, thereby causing the atmosphere to flow toward the exhaust port 13a. The flow-conditioning plate 24 is formed of a metal material such as aluminum, an aluminum alloy, or stainless steel. The flow-conditioning plate 24 is not an essential component in the microwave heating apparatus 1, and may not be installed.

### <Temperature-Measuring Unit>

The microwave heating apparatus 1 further includes a plurality of radiation thermometers 26 for measuring surface temperatures on the back side of the wafer W, and a temperature-measuring unit 27 connected to the plurality of radiation thermometers 26. In FIG. 1, the other radiation thermometers 26 except a radiation thermometer 26 for measuring a surface temperature in a central region of the back side of the wafer W are not shown.

### <Microwave Radiation Space>

In the microwave heating apparatus 1 of this embodiment, a space defined by the ceiling portion 11, the four side wall portions 12 and the flow-conditioning pate 24 in the treatment container 2 form a microwave radiation space S. In the microwave radiation space S, microwaves are radiated from the plurality of microwave introduction ports 10 provided in the ceiling portion 11. Since the ceiling portion 11, the four side wall portions 12 and the flow-conditioning plate 24 in the treatment container 2 are all formed of a metallic material, they reflect and scatter the microwaves within the microwave radiation space S.

### <Microwave Introduction Device>

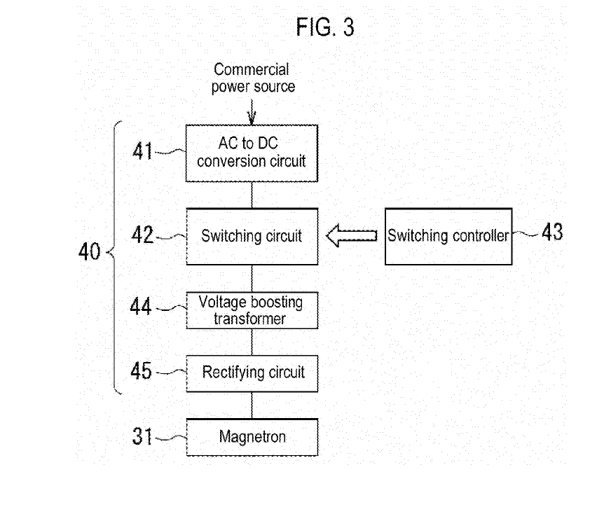

Subsequently, the configuration of the microwave introduction device 3 will be described with reference to FIGS. 1, 2 and 3. FIG. 3 is an explanatory view showing a schematic configuration of the high-voltage power supply unit of the microwave introduction device 3. As described above, the microwave introduction device 3 is mounted at the top of the treatment container 2, and functions as a microwave introduction means for introducing electromagnetic waves (microwaves) into the treatment container 2. As shown in FIG. 1, the microwave introduction device 3 has a plurality of microwave units 30 for introducing microwaves into the treatment container 2, and a high-voltage power supply unit 40 connected to the plurality of microwave units 30.

### <Microwave Unit>

In this embodiment, the configurations of the plurality of microwave units 30 are all the same. Each of the microwave units 30 has a magnetron 31 for generating microwaves used for processing the wafer W, a waveguide 32 acting as a transmission channel for transmitting the microwaves generated in the magnetron 31 to the treatment container 2, and a transmissive window 33 fixed to the ceiling portion 11 to close the microwave introduction port 10. The magnetron 31 corresponds to a microwave source in the present disclosure.

As shown in FIG. 2, in this embodiment, the treatment container 2 has four microwave introduction ports 10 equidistantly disposed in the circumferential direction in the ceiling portion 11. Each of the microwave introduction ports 10 has a rectangular shape with long sides and short sides as viewed in a plane. The size of each of the microwave introduction ports 10 or a ratio of long sides to short sides may be different for each of the microwave introduction ports 10, although all four microwave introduction ports 10 may have the same size and shape in terms of enhancement of the uniformity of an annealing treatment on the wafer W and improvement of controllability. Moreover, in this embodiment, the microwave units 30 are connected to the microwave introduction ports 10, respectively. That is, the number of microwave units 30 is four.

The magnetron 31 has positive and negative electrodes (both of which are not shown) to which a high voltage supplied by the high-voltage power supply unit 40 is applied. Furthermore, a magnetron capable of oscillating microwaves of various frequencies may be used as the magnetron 31. For the microwaves generated by the magnetron 31, an optimum frequency is selected every time an object is to be treated. For example, in the annealing treatment, the microwave may be a microwave with a high frequency such as 2.45 GHz or 5.8 GHz. Particularly, the microwave may also be a microwave of 5.8 GHz.

The waveguide 32 has a rectangular shape in cross section and is also in the form of a rectangular tub, and extends upwardly from the top surface of the ceiling portion 11 of the treatment container 2. The magnetron 31 is connected to the waveguide 32 near an upper end of the waveguide 32. A lower end of the waveguide 32 abuts on the top surface of the transmissive window 33. The microwaves generated by the magnetron 31 are introduced into the treatment container 2 through the waveguide 32 and the transmissive window 33.

The transmissive window 33 is formed of a dielectric material. For example, quartz, ceramic or the like may be used as the material for the transmissive window 33. The interface between the transmissive window 33 and the ceiling portion 11 is hermetically sealed by a seal member (not shown). A distance (gap G) from a bottom surface of the transmissive window 33 to the surface of the wafer W supported by the support pins 16 may be, for example, 25 mm or more, in terms of suppression of direct radiation of microwaves onto the wafer W. The distance may also be adjusted, in s some embodiments, within a range of 25 to 50 mm.

The microwave unit 30 further has a circulator 34, a detector 35 and a tuner 36 installed along the path of the waveguide 32; and a dummy load 37 connected to the circulator 34. The circulator 34, the detector 35 and the tuner 36 are installed in this order from the upper end of the waveguide 32. The circulator 34 and the dummy load 37 constitute an isolator for isolating reflected waves from the treatment container 2. That is, the circulator 34 induces the reflected waves from the treatment container 2 to the dummy load 37, and the dummy load 37 converts the reflected waves induced by the circulator 34 into heat.

The detector 35 is used to detect the reflected waves from the treatment container 2 in the waveguide 32. The detector 35 is comprised of, for example, an impedance monitor, specifically, a standing wave monitor for detecting an electric field of a standing wave in the waveguide 32. The standing wave monitor may be comprised of three pins protruding into the internal space of the waveguide 32. The location, phase and intensity of the electric field of the standing wave can be detected by the standing wave monitor, thereby detecting reflected waves from the treatment container 2. Moreover, the detector 35 may be comprised of a directional coupler capable of detecting progressive waves and reflected waves.

The tuner 36 has a function of performing impedance matching (hereinafter, also simply referred to as ‘matching’) between the magnetron 31 and the treatment container 2. The matching using the tuner 36 is performed based on a detection result of the reflected waves in the detector 35. The tuner 36 may be comprised of, for example, a conductor plate (not shown) installed to be loaded into and unloaded from the internal space of the waveguide 32. In this case, the amount of the conductor plate protruding into the internal space of the waveguide 32 can be controlled, thereby regulating the electric energy of the reflected waves so as to adjust impedance between the magnetron 31 and the treatment container 2.

### <High-Voltage Power Supply Unit>

The high-voltage power supply unit 40 supplies a high voltage for generating microwaves to the magnetron 31. As shown in FIG. 3, the high-voltage power supply unit 40 has an AC to DC conversion circuit 41 connected to a commercial power source, a switching circuit 42 connected to the AC to DC conversion circuit 41, a switching controller 43 for controlling operations of the switching circuit 42, a voltage boosting transformer 44 connected to the switching circuit 42, and a rectifying circuit 45 connected to the voltage boosting transformer 44. The magnetron 31 is connected to the voltage boosting transformer 44 with the rectifying circuit 45 interposed therebetween.

The AC to DC conversion circuit 41 is a circuit for rectifying AC from a commercial power source (e.g., AC of three-phase 200 V) to convert it into DC of a predetermined waveform. The switching circuit 42 is a circuit that controls turning on or off of the DC converted by the AC to DC conversion circuit 41. In the switching circuit 42, phase-shift type pulse width modulation (PWM) control or pulse amplitude modulation (PAM) control is performed by the switching controller 43, thereby generating a pulse-shaped voltage waveform. The voltage boosting transformer 44 is to boost the voltage waveform output from the switching circuit 42 up to a predetermined magnitude. The rectifying circuit 45 is a circuit for rectifying the voltage boosted by the voltage boosting transformer 44 and supplying the rectified voltage to the magnetron 31.

### <Control Unit>

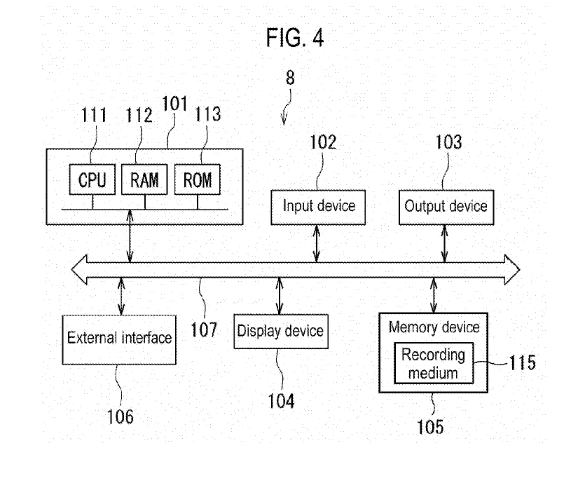

Each of the components of the microwave heating apparatus 1 is connected to and controlled by the control unit 8. The control unit 8 is typically a computer. FIG. 4 illustrates an example of a hardware configuration of the control unit 8 shown in FIG. 1. The control unit 8 includes a main controller 101, an input device 102 such as a keyboard or mouse, an output device 103 such as a printer, a display device 104, a memory device 105, an external interface 106, and a bus 107 for connecting them to one another. The main controller 101 has a CPU (Central Processing Unit) 111, a RAM (Random Access Memory) 112, and a ROM (Read Only Memory) 113. The memory device 105, which is not limited to a specific form so long as it can memorize information, may be, for example, a hard disk device or optical disk device. Furthermore, the memory device 105 records information on a computer-readable recording medium 115, and also reads information from the recording medium 115. The recording medium 115, which is not limited to a specific form so long as it can memorize information, may be, for example, a hard disk, an optical disk, a flash memory, or the like. The recording medium 115 may be a recording medium on which a recipe for a microwave heating method according to this embodiment has been recorded.

In the control unit 8, the CPU 111 executes a program stored in the ROM 113 or the memory device 105 while using the RAM 112 as a working area, thereby heating the wafer W in the microwave heating apparatus 1 of this embodiment. Specifically, in the microwave heating apparatus 1, the control unit 8 controls each of the components (e.g., the microwave introduction device 3, the supporting device 4, the gas supply device 5a, the evacuation device 6, and the like) related to process conditions including, for example, the temperature of the wafer W, the pressure in the treatment container 2, the flow rate of a gas, a microwave output, the rotation speed of the wafer W, and the like.

In the microwave heating apparatus 1 configured as described above, a variation in heating temperature in the surface of the wafer W is suppressed, thereby enabling a uniform heating. In a process of fabricating a semiconductor device, the microwave heating apparatus 1 can be used for the purpose of an annealing treatment and the like, for example.

### <Microwave Heating Method>

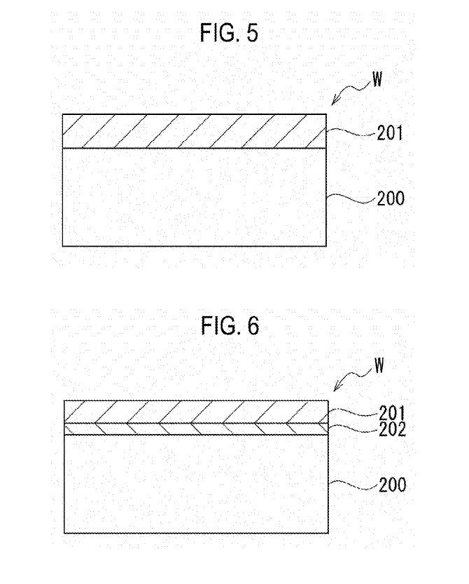

Subsequently, a microwave heating method performed using the microwave heating apparatus 1 will be described. First, the wafer W as an object to be treated in the microwave heating method of this embodiment will be described with reference to FIGS. 5 to 8. FIG. 5 schematically illustrates a sectional structure of an example of the wafer W. As shown in FIG. 5, the wafer W has a substrate body 200, and a film to be annealed 201 formed on the substrate body 200. Further, in the substrate body 200 of the wafer W in the form of a plate, the top surface of the top and bottom surfaces having wide areas is a forming surface for a semiconductor device.

The material of the substrate body 200 may include, but is not particularly limited to, a semiconductor, for example. For example, a compound semiconductor such as GaP (gallium phosphide), GaAs (gallium arsenide), InP (indium phosphide), GaN (gallium nitride), SiC (silicon carbide) and the like, in addition to silicon (Si) or germanium (Ge), may be used as the semiconductor constituting the substrate body 200.

The film to be annealed 201 may include, for example, a metallic film, an insulating film, and a semiconductor film. Here, the material of the metallic film may include, for example, titanium (Ti), nickel (Ni), cobalt (Co), aluminum (Al), copper (Cu), tungsten (W), germanium (Ge), platinum (Pt), hafnium (Hf), and alloys thereof; and the like. The material may be a combination of two or more thereof.

An aspect of the microwave heating method of this embodiment may include a process in which if the material of the substrate body 200 is silicon and the film to be annealed 201 is a metallic film, silicidation is achieved by performing an annealing treatment on the metallic film. In this case, for example, as shown in FIG. 6, the metal of the film to be annealed 201 is silicidized by the annealing treatment, thereby forming a metallic silicide layer 202. Moreover, another aspect of the microwave heating method of this embodiment may include, for example, a process of recovering a defect in the film to be annealed 201, and the like.

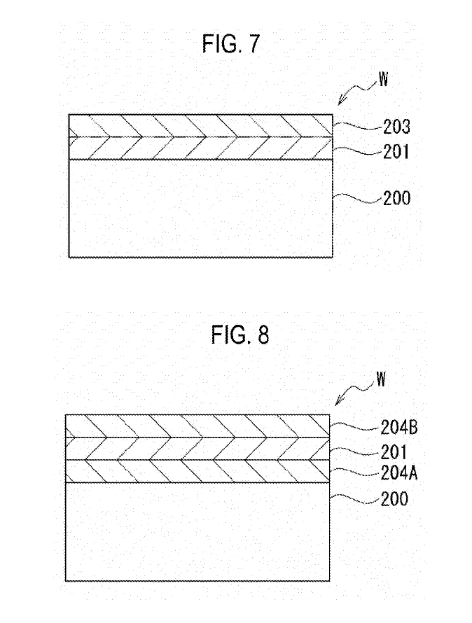

FIG. 7 schematically illustrates a sectional structure of another example of an object to be treated, which has a film to be annealed and a substrate body. In the example shown in FIG. 7, the wafer W has a substrate body 200, a film to be annealed 201 formed on the substrate body 200, and a material film 203 formed on the film to be annealed 201. Here, there is no limitation on the kind of the material film 203. As in this example, the film to be annealed 201 is not limited to a case where the film to be annealed 201 exists on the outermost surface of the wafer W, and another film may be formed on an upper layer of the wafer W.

FIG. 8 schematically illustrates a sectional structure of a further example of an object to be treated, which has a film to be annealed and a substrate body. In the example shown in FIG. 8, the wafer W has a substrate body 200, a first material film 204A formed on the substrate body 200, a film to be annealed 201 formed on the first material film 204A, and a second material film 204B formed on the film to be annealed 201. Here, there is no limitation on the kinds of the first material film 204A and the second material film 204B, and the material films may include a plurality of material layers. As in this example, if the purpose of the annealing treatment is other than silicidation of the film to be annealed 201, another material film may exist between the substrate body 200 and the film to be annealed, and may be formed on an upper layer of the film to be annealed 201.

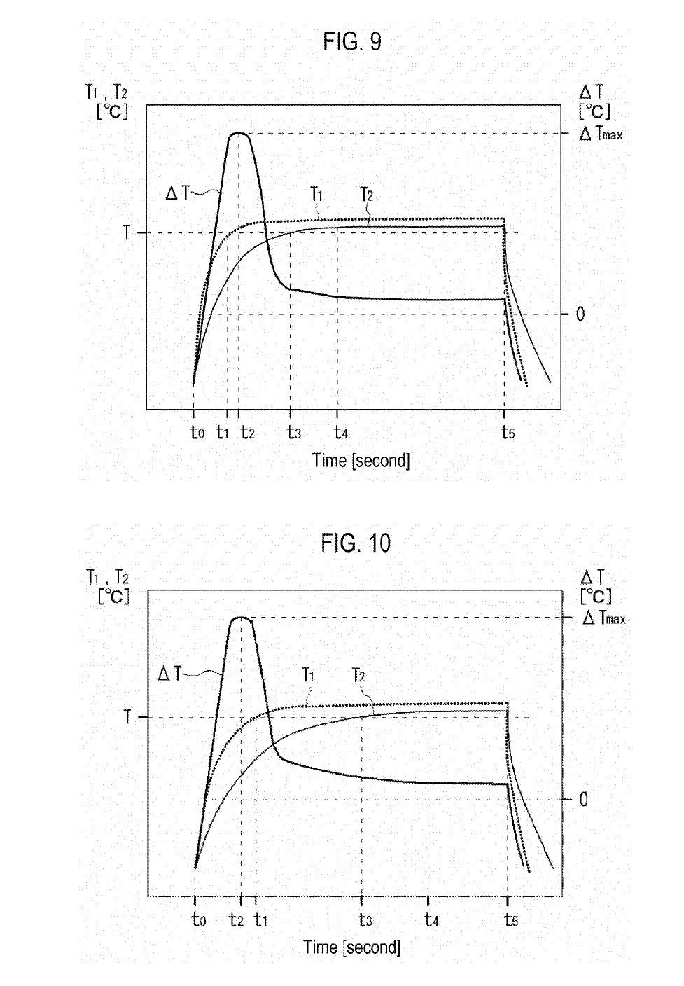

The microwave heating method of this embodiment includes the following first and second steps. FIG. 9 is a graph showing an example of temperature rising behavior of the film to be annealed 201 and the substrate body 200 when, in a structure similar to that of FIG. 5, the film to be annealed 201 is a metallic film and an annealing treatment is performed on the wafer W of which the substrate body 200 is a silicon, by microwave irradiation. The graph of FIG. 9 is plotted by installing radiation thermometers on both the upper side (the front side of the film to be annealed 201; e.g., a position denoted by reference numeral 26′ in FIG. 1) and the lower side (the back side of the substrate body 200) of the wafer W, and individually measuring temperatures of the film to be annealed 201 and the substrate body 200. The left ordinate axis on the paper plane of FIG. 9 represents a temperature T₁ of the film to be annealed 201 or a temperature T₂ of the substrate body 200, and the right ordinate axis on this figure represents a temperature difference ΔT (=T₁−T₂) between these temperatures. The abscissa axis of FIG. 9 represents the elapse of time. In this annealing treatment, the microwave irradiation is initiated from t₀, and is stopped at t₅. Between times t₀ and t₅, the temperature T₁ of the film to be annealed 201 reaches a heating target temperature T at time t₁, ΔT becomes a maximum at time t₂, the temperature T₂ of the substrate body 200 reaches the heating target temperature T at time t₃, and the temperature T₂ of the substrate body 200 reaches a steady state at time t₄.

### <First Step>

For the microwave heating method of this embodiment, in the first step, the film to be annealed 201 and the wafer W having the substrate body 200 with the film to be annealed 201 formed thereon are heated by irradiating them with microwaves. Specifically, in the microwave heating apparatus 1, microwaves are generated by applying a voltage from the high-voltage power supply unit 40 to the magnetron 31 under control of the control unit 8. The microwaves generated in the magnetron 31 are propagated in the waveguide 32, also transmitted through the transmissive window 33, and then introduced into a space above the wafer W in the treatment container 2. The power of the microwaves is different depending on the kind of the film to be annealed 201, a film thickness, or a purpose of the annealing treatment, although the sum of the power for four microwave introduction ports 10, for example, is within a range of 500 W to 4000 W. In this embodiment, the plurality of magnetrons 31 may sequentially generate microwaves, so that the microwaves are alternately introduced into the treatment container 2 from the respective microwave introduction ports 10. Alternatively, the plurality of magnetrons 31 may simultaneously generate a plurality of microwaves, so that the microwaves are simultaneously introduced into the treatment container 2 from the respective microwave introduction ports 10.

The wafer W is irradiated with the microwaves introduced into the treatment container 2, so that the film to be annealed 201 of the wafer W is quickly heated by electromagnetic wave heating, e.g., induction heating, Joule heating, magnetic heating, or the like. As a result, an annealing treatment is performed on the wafer.

### <Second Step>

For the microwave heating method of this embodiment, in the second step, the microwave irradiation is stopped. That is, the application of the voltage from the high-voltage power supply unit 40 to the magnetron 31 is stopped under the control of the control unit 8. The second step may include a cooling time required for lowering the temperature of the wafer W after the microwave irradiation is stopped.

<Switching from First Step to Second Step>

For the microwave heating method of this embodiment, switching from the first step to the second step is performed under the control of the control unit 8. First, the timing of the switching is after the temperature T₁ of the film to be annealed 201 reaches a temperature equal to or greater than the heating target temperature T of the film to be annealed 201 by the microwave irradiation. The purpose (e.g., silicidation) of the annealing treatment is achieved on the premise that the film to be annealed 201 will be heated up to a temperature range greater than the heating target temperature T. In the example shown in FIG. 9, the temperature of the film to be annealed 201 reaches the heating target temperature T at time t₁, and it is necessary to continue the microwave irradiation at least until time t₁.

Second, the switching timing is a time shorter than time t₄ at which the temperature of the substrate body 200 reaches the steady state. Here, the ‘steady state’ means a state where the temperature becomes almost constant when the microwave irradiation is continued under the same condition, and a case where a variation in temperature becomes, for example, within ±3% may be determined as the steady state. After time t₄ at which the temperature of the substrate body 200 reaches the steady state, thermal diffusion between the film to be annealed 201 and the substrate body 200 is dominant. Hence, the temperature rising reaches a limit, and the film to be annealed 201 cannot be selectively heated. Furthermore, the continued microwave irradiation even after time t₄ at which the temperature of the substrate body 200 reaches the steady state means that heating is performed at a higher temperature and/or an unnecessarily longer time than a minimum heating temperature and heating time required for the annealing treatment. Accordingly, the advantages of the microwave irradiation that internal heating, local heating and selectable heating are enabled, cannot be sufficiently utilized. That is, there is a problem that throughput decreases or power consumption increases due to microwave irradiation for an unnecessarily longer time after time t₄ at which the temperature of the substrate body 200 reaches the steady state. As a result, the thermal budget for the entire wafer W increases.

In the conventional microwave heating method, as described above, the temperature of the film to be annealed 201 is estimated by measuring the temperature T₂ of the substrate body 200. Therefore, the time at which the temperature T₂ reaches the heating target temperature T of the film to be annealed 201, is used as a reference even when the end point of the microwave irradiation is determined while measuring the temperature T₂ of the substrate body 200 in real time or even when the time of the microwave irradiation is set based on a change in previously measured temperature T₂. In order to ensure the integrity of annealing, the microwave irradiation is continued even after time t₄ at which the temperature of the substrate body 200 reaches the steady state in FIG. 9, so that time t₅ is set to the end point of the microwave irradiation, for example. In the microwave irradiation, induction heating is dominant, and hence the electric field intensity of microwaves becomes maximum near the surface of the wafer W due to the skin effect. Since a temperature rising rate depends on the electric field intensity, for example, when an annealing treatment is performed on the wafer W of the structure shown in FIG. 5, the temperature rising rate of the film to be annealed 201 at the front side thereof is higher than that of the substrate body 200, and heated up to a higher temperature than the substrate body 200. For example, as shown in FIG. 9, since the temperature rising rate of the film to be annealed 201 by the microwave irradiation is higher than that of the substrate body 200, the temperature of the film to be annealed 201 reaches the heating target temperature T at time t₁. Thus, the minimum microwave irradiation time required for the annealing treatment of the film to be annealed 201 is t₀ to t₁, and the switching from the first step to the second step is performed at time t₁, thereby minimizing throughput and power consumption and simultaneously effectuating the most reduction of the thermal budget for the entire wafer W.

Further, in FIG. 9, the film to be annealed 201 is locally or selectively heated by the microwaves at time t₂ at which ΔT becomes maximum and before/after time t₂, and hence efficient heating can be first performed on the film to be annealed 201 using the difference in temperature rising rate between the film to be annealed 201 and the substrate body 200. That is, in the vicinity of time t₂ at which ΔT becomes maximum, it is possible to apply heat required for silicidation or a phase change to a thin film in a state where a thermal load to a substrate is reduced as much as possible. Thus, if the microwave irradiation is continued even after time t₁ at which the temperature of the film to be annealed 201 reaches the heating target temperature T in order to enhance the integrity of the annealing treatment, the switching from the first step to the second step is performed at or before a time that reaches time t₂, so that it is possible to perform an efficient annealing treatment effectively using the difference in temperature rising rate between the film to be annealed 201 and the substrate body 200. That is, as compared with the conventional method, it is possible to perform an annealing treatment in which throughput and power consumption are remarkably decreased and the thermal budget for the entire wafer W is suppressed.

Further, in the example shown in FIG. 9, if the microwave irradiation is continued even after time t₁ in order to enhance the integrity of the annealing treatment, the switching from the first step to the second step is performed before time t₄, or until time t₃, so that, as compared with the conventional method, it is possible to perform an annealing treatment in which throughput and power consumption are remarkably decreased and the thermal budget for the entire wafer W is suppressed.

FIG. 10 is a graph showing another example of temperature rising behaviors of the film to be annealed 201 and the substrate body 200 when heating by microwave irradiation is performed on the wafer W of the structure similar to that of FIG. 5. In the graph of FIG. 9, a relationship between time t₁ at which the temperature T₁ of the film to be annealed 201 reaches the heating target temperature T and the time t₂ at which ΔT becomes maximum is t₁<t₂. On the contrary, the graph of FIG. 10 is similar to that of FIG. 9 but different therefrom only in that a relationship between time t₁ at which the temperature T₁ of the film to be annealed 201 reaches the heating target temperature T and time t₂ at which ΔT becomes maximum, is t₁≧t₂. That is, in the annealing treatment, the microwave irradiation is started from time t₀ and stopped at time t₅. Between time t₀ and time t₅, ΔT becomes maximum at time t₂, the temperature T₁ of the film to be annealed 201 reaches the heating target temperature T at time t₁, the temperature T₂ of the substrate body 200 reaches the heating target temperature T at time t₃, and the temperature of the substrate body 200 reaches the steady state at time t₄.

As shown in FIG. 10, the film to be annealed 201 has a higher temperature rising rate by the microwave irradiation than that of the substrate body 200, and hence the temperature T₁ of the film to be annealed 201 reaches the heating target temperature T at time t₁. Thus, the minimum microwave irradiation time required for the annealing treatment of the film to be annealed 201 is t₀ to t₁. Further, since time t₂ at which ΔT becomes maximum is between t₀ and t₁, the film to be annealed 201 is locally and also selectively heated by microwaves, so that heating can be first performed on the film to be annealed 201, using the difference in temperature rising rate between the film to be annealed 201 and the substrate body 200 as much as possible. That is, even in the case of t₁≧t₂, the switching from the first step to the second step is performed at time t₁, so that it is possible to minimize throughput and power consumption and simultaneously to minimize the thermal budget for the entire wafer W.

Moreover, in the example of FIG. 10, if the microwave irradiation is continued even after time t₁ in order to enhance the integrity of the annealing treatment, the switching from the first step to the second step is performed before time t₄, or until time t₃, so that, as compared with the conventional method, it is possible to perform an annealing treatment in which throughput and power consumption are remarkably decreased and the thermal budget for the entire wafer W is suppressed.

As described above, in the microwave heating method of this embodiment, the switching from the first step to the second step is performed before time t₄ at which the temperature of the substrate body 200 reaches the steady state, or until time t₃ at which the temperature T₂ of the substrate body 200 reaches the heating target temperature T, in some embodiments at time t₁ at which the temperature T₁ of the film to be annealed 201 reaches the heating target temperature T, so that it is possible to suppress harmful effects caused by excessive microwave irradiation and efficiently perform an annealing treatment on the film to be annealed 201 for a short time.

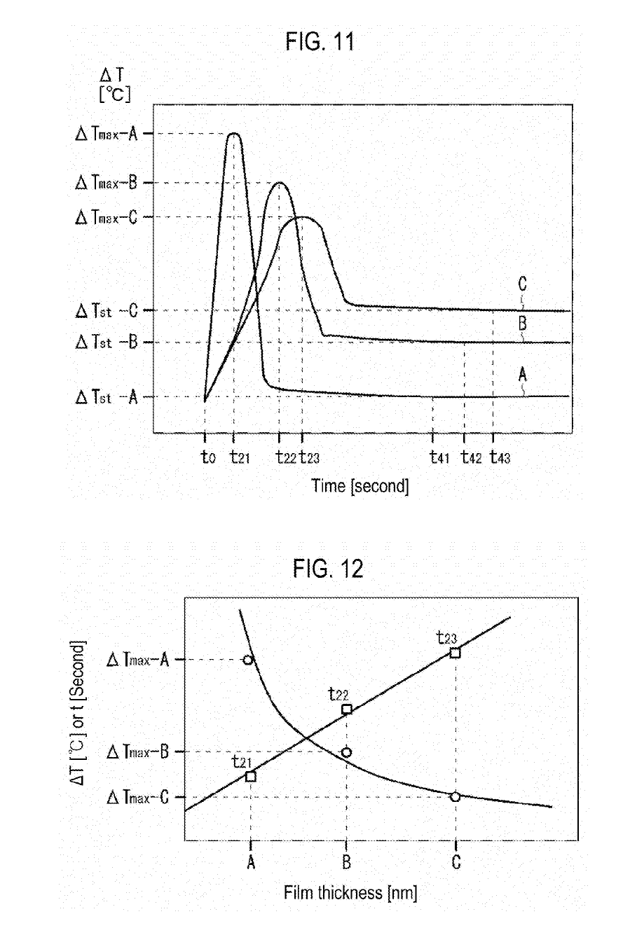

FIG. 11 is a graph showing a relationship between the film thickness of the film to be annealed 201 and ΔT. The ordinate axis of FIG. 11 represents ΔT, and the abscissa axis represents an elapse time of an annealing treatment. Curves A to C in FIG. 11 correspond to relative magnitude relationships of film thicknesses of the film to be annealed 201, meaning that the film thicknesses increase in the order of Curve A<Curve B<Curve C. FIG. 12 is a graph in which ΔT of FIG. 11 or time t until ΔT is represented on the ordinate axis and the film thickness is represented on the abscissa axis.

From FIGS. 11 and 12, as the film thickness of the film to be annealed 201 becomes smaller, the maximum value ΔTmax of ΔT generated in the temperature rising process of the film to be annealed 201 becomes higher and is shown in a short time. On the contrary, as the film thickness of the film to be annealed 201 becomes larger, ΔTmax becomes smaller, and more time is taken until ΔTmax occurs. Specifically, in Curve A in which the film thickness is small, ΔTmax is the highest value and is expressed at the fastest time t₂₁. In Curve C in which the film thickness is large, ΔTmax is the lowest value and is expressed at the latest time t₂₃. In Curve B, the magnitude of ΔTmax and time t₂₂ are all positioned between Curves A and C. As such, a relationship close to direct proportion is shown between the film thickness of the film to be annealed 201 and the time t (t₂₁, t₂₂, t₂₃) until ΔTmax is expressed. On the contrary, a relationship close to inverse proportion is shown between the film thickness of the film to be annealed 201 and the magnitude of ΔTmax.

From FIG. 11, as the film thickness of the film to be annealed 201 becomes smaller, a value ΔTst when ΔT is in the steady state becomes smaller, and the steady state of ΔT is also shown in a short time. As the film thickness of the film to be annealed 201 becomes larger, ΔTst becomes larger, and more time is taken until ΔT is in the steady state. Specifically, in Curve A in which the film thickness is small, ΔTst is the lowest value and is expressed at the fastest time t₄₁. In Curve C in which the film thickness is large, ΔTst is the highest value and is expressed at the latest time t₄₃. In Curve B, the magnitude of ΔTst and time t₄₂ are all positioned between Curves A and C. Here, the ‘steady state’ of ΔT means a state where AT becomes almost constant when the microwave irradiation is continued under the same condition. For example, a case where a variation in ΔT is within ±3% may be determined as the steady state of ΔT.

The reason why ΔT of the film to be annealed 201 shows behaviors as shown in FIGS. 11 and 12 is as follows. As described above, the electric field intensity of microwaves becomes greatest near the surface of the wafer W due to the skin effect. Accordingly, for example, if the wafer W of the structure shown in FIG. 5 is subjected to an annealing treatment, the smaller the film thickness of the film to be annealed 201 becomes, the larger the skin depth occupying in the thickness of the film to be annealed 201 becomes. Thus, in a temperature rising process in which induction heating is dominant, the smaller the film thickness of the film to be annealed 201 becomes, the higher the temperature rising rate becomes, and ΔTmax is shown in a short time. In addition, the film to be annealed 201 can be further heated up to a higher temperature. Meanwhile, since the thermal diffusion between the film to be annealed 201 and the substrate body 200 is dominant in the steady state of ΔT, the smaller the film thickness of the film to be annealed 201 becomes, the smaller the thermal capacity becomes. Therefore, it is considered that ΔT, a temperature difference between the film to be annealed 201 and the substrate body 200, becomes small.

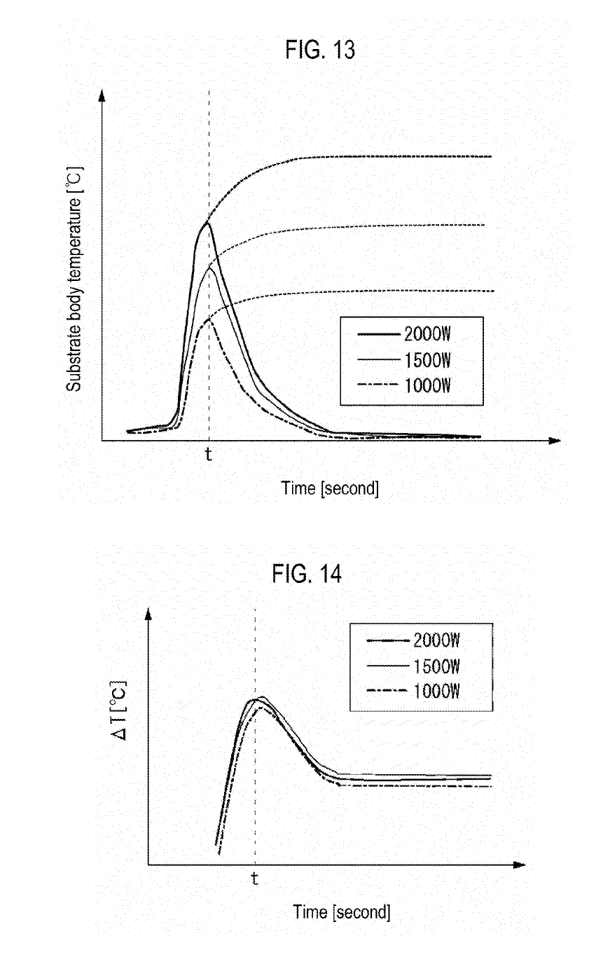

Next, experimental results obtained by performing an annealing treatment on the film to be annealed 201 while changing microwave power will be described with FIGS. 13 and 14. An object obtained by forming a Ni film with a thickness of 30 nm as the film to be annealed 201 on a silicon wafer as the substrate body 200, is used as an object to be treated. In the microwave heating apparatus 1, microwaves are turned on and the object to be treated is irradiated with the microwaves having 1000 W, 1500 W and 2000 W as the sum of powers of four microwave introduction ports 10 for 30 seconds, and the microwaves are then turned off to stop the irradiation. During the annealing treatment, the temperature of the silicon wafer (back side) and the temperature of the Ni film (front side) are measured. The measured results are shown in FIGS. 13 and 14. The ordinate axis of FIG. 13 represents the measured temperature of the silicon wafer, and the abscissa axis represents an elapsed time. A dash line portion in each curve of FIG. 13 is a temperature rising curve of the silicon wafer when the microwave irradiation is continued without an interruption of 30 seconds. The ordinate axis of FIG. 14 represents ΔT, and the abscissa axis represents an elapsed time. From FIG. 13, the temperature of the silicon wafer as the substrate body 200 is changed in correspondence with the magnitude of microwave power. That is, it can be seen that, if the microwave power increases to 1000 W, 1500 W and 2000 W, the temperature of the silicon wafer also increases accordingly. That is, the microwave power and the temperature of the silicon wafer have a relationship almost close to direct proportion. Meanwhile, it can be seen from FIG. 14 that time t₂ at which ΔT becomes maximum is almost the same in any of 1000 W, 1500 W and 2000 W.

In FIGS. 13 and 14, considering that time t₂ at which ΔT becomes maximum is almost constant without relying on the microwave power, the switching from the first step to the second step is performed such that time t₂ at which ΔT becomes maximum is included in any microwave power. Accordingly, it is possible to reduce the microwave irradiation time while maximally obtaining the benefit of selectable heating. Further, since time t₂ at which ΔT becomes maximum is almost constant, it is understood that by causing the microwave power to be varied, the heating temperature can be adjusted without greatly changing a process time. Thus, in the microwave heating apparatus 1, the microwave power is changed under control of the control unit 8, so that an annealing treatment can be performed on the film to be annealed 201 at a desired temperature in a short time.

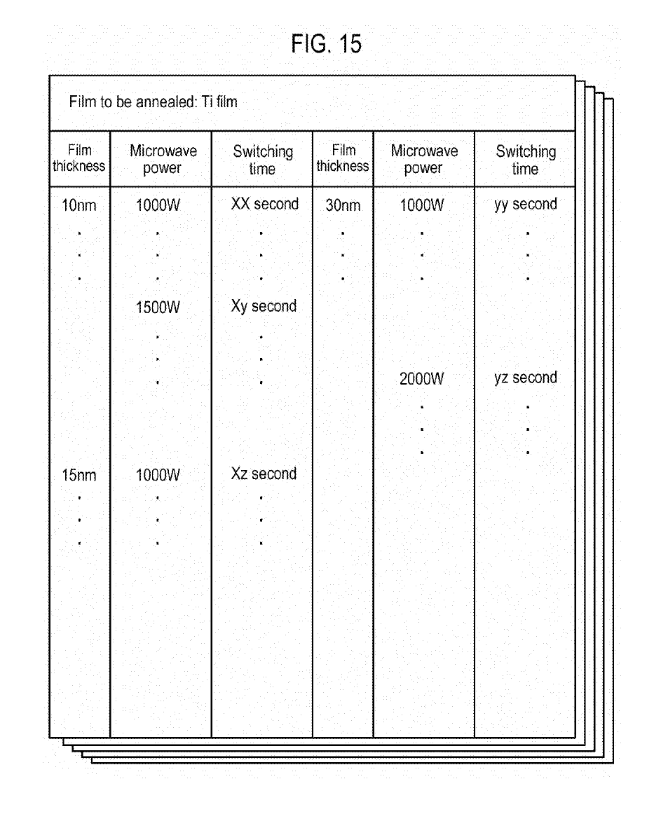

Based on the knowledge described above, in the microwave heating method of this embodiment, the thermal behavior of the film to be annealed 201 has been previously measured in an experimental manner, and the timing of the switching from the first step to the second step utilizes, based on the measured thermal behavior, timings stored as a portion of a recipe in the control unit 8 of the microwave heating apparatus 1. Specifically, a table is prepared in which the timings of the switching from the first step to the second step are caused to correspond to the material and film thickness of the film to be annealed 201, the microwave power and the like, based on measured data such as temperatures T₁ and T₂, ΔT, ΔTst, times t₁, t₂, t₃, t₄, t₂₁, t₂₂, t₂₃, t₄₁, t₄₂, t₄₃ and the like. For example, FIG. 15 illustrates an example of a table in which the timings of the switching from the first step to the second step correspond to such measured data when the film to be annealed 201 is a Ti film. The table of FIG. 15 shows the switching timing for every film thickness and every microwave power in the case of the Ti film. Further, the microwave power is the sum of four microwave introduction ports 10. The table may be stored in the memory device 105 of the control unit 8 or in the computer-readable recording medium 115. In an actual annealing treatment, the timing of the switching from the first step to the second step may be read and used from the table, according to the material and film thickness of the film to be annealed 201 or the microwave power.

Further, in the microwave heating method of this embodiment, the temperature of the film to be annealed 201 may be estimated in real time from a table similar to FIG. 15, which is stored in the memory device 105 or the computer-readable recording medium 115, based on results of the surface temperature at the back side of the substrate body 200, which are measured by the temperature-measuring unit 27, thereby determining the timing of the switching from the first step to the second step.

As described above, in the microwave heating method of this embodiment, the timing of the switching from the first step to the second step may be determined based on temperature rising data of the film to be annealed 201 and temperature rising data of the substrate body 200, which have been previously obtained in the experimental manner. In this case, the temperature rising data may be prepared according to the film thickness and material of the film to be annealed 201 and the magnitude of the microwave power.

In the microwave heating method of this embodiment, the first and second steps may be repeatedly performed twice or more for one sheet of wafer W. By repeating the first and second steps twice or more, there is an advantage in that an amount of heat required for treatment of a thin film can be supplied in a state where the temperature of the substrate is lowered as much as possible. In this case, from the second step, a time until the next first step starts may be, for example, in the range of 30 to 120 seconds, in consideration of a cooling time required for lowering the temperature of the wafer W.

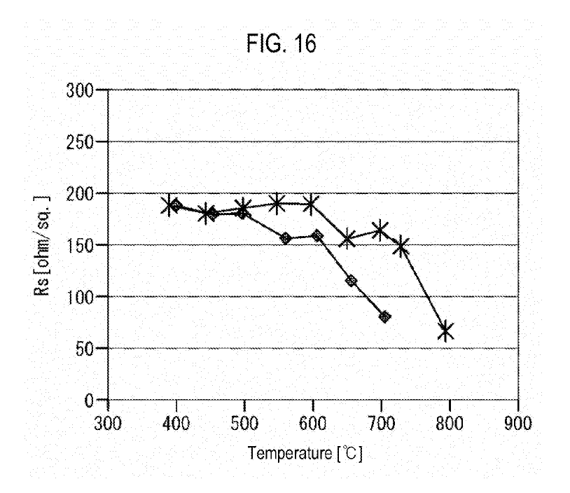

Then, experimental results obtained by performing an annealing treatment on the film to be annealed 201 while changing temperature, will be described with reference to FIG. 16. An object to be treated is obtained by sequentially forming a Ti layer with a thickness of 2 nm and a TiN layer with a thickness of 5 nm on a silicon wafer as the substrate body 200. Using the microwave heating apparatus 1 for the object to be treated, an annealing treatment is performed on the Ti layer as the film to be annealed 201 so that the Ti layer is silicidized. In the annealing treatment, microwaves are turned on and the microwaves are irradiated with powers of 3000 to 6000 W for 10 to 60 seconds, and the irradiation is then stopped by turning off the microwaves (see the line with symbol ♦ in FIG. 16). Further, for the purpose of comparison, RTA (Rapid Thermal Anneal) using a lamp heating method is performed using the same ON/OFF time for the same object to be treated (see the line with symbol * in FIG. 16). These results are shown in FIG. 16. FIG. 16 illustrates a formation curve of Ti silicide. The ordinate axis of FIG. 16 represents a surface resistance Rs of the Ti layer after the annealing treatment, and the abscissa axis represents a temperature of the back side of the silicon wafer. As a silicide layer (TiSi layer or TiSi₂ layer) forms by the annealing treatment, the surface resistance of the Ti film becomes small. It is found from FIG. 16 that with the microwave heating method of this embodiment, the silicide layer can be formed at a lower heating temperature (on the back side of the silicon wafer) as compared with the lamp heating method. Since the microwave irradiation time in this experiment was not optimized in view of the throughput improvement or the suppression effect of power consumption/thermal budget, it is possible to form the silicide layer at a remarkably lowered temperature by performing the optimization of the microwave irradiation time.

### <Specific Procedure of Heating>

Next, a specific procedure of an annealing treatment using the microwave heating apparatus 1 will be described. First, a command for performing an annealing treatment in the microwave heating apparatus 1 is input, for example, from an input device of the control unit 8. Subsequently, the main controller 101 receives the command and reads a recipe stored in the memory device 105 or the computer-readable recording medium 115. Then, a control signal is transmitted from the main controller 101 to respective end devices (e.g., the microwave introduction device 3, the supporting device 4, the gas supply device 5a, the evacuation device 6, and the like) of the microwave heating apparatus 1 so that the annealing treatment is performed according to a condition based on the recipe.

The gate valve GV is then in the opened state, and the wafer W on which the film to be annealed 201 has been formed is introduced into the treatment container 2 through the gate valve GV and the loading/unloading port 12a by a carrier device (not shown) and is loaded on the plurality of support pins 16. The lifting drive unit 18 is actuated to displace the plurality of support pins 16, so that the wafer W is set at a predetermined height. At this height, the rotary drive unit 17 is actuated under the control of the control unit 8, if necessary, so that the wafer W may be rotated in the horizontal direction at a predetermined speed. As the wafer W is rotated, the microwaves irradiated onto the wafer W can be less biased, thereby achieving the uniformity of heating temperature in the plane of the wafer W. In this case, the rotation of the wafer W may not be continuous but discontinuous.

Then, the gate valve GV is in the closed state, and the interior of the treatment container 2 is depressurized and evacuated by the evacuation device 6, if necessary. Subsequently, if necessary, process gases are introduced into the treatment container 2 by the gas supply device 5a. The internal space of the treatment container 2 is regulated to a predetermined pressure by adjusting the amount of exhaust and the amounts of the process gases to be supplied.

Subsequently, under the control of the control unit 8, the annealing treatment including the first and second steps is performed on the wafer W maintained at the predetermined height. The switching from the first step to the second step is performed by transmitting a control signal for stopping the microwave irradiation from the main controller 101 to the microwave introduction device 3.

If necessary, the annealing treatment including the first and second steps may be repeated plural times.

A control signal for terminating the annealing treatment is transmitted from the main controller 101 to each of end devices of the microwave heating apparatus 1 to finally terminate the annealing treatment. The control signal stops the rotation of the wafer W and the supply of the process gases to terminate the annealing treatment on the wafer W. After the annealing treatment for a predetermined time or a cooling treatment after the annealing treatment is terminated, the gate valve GV is in the opened state, and the height of the wafer W is adjusted by the supporting device 4. Then, the wafer W is taken out by a carrier device (not shown).

The procedure may be performed by causing a plurality of software applications to cooperate with one another under the control of the control unit 8.

As described above, according to the microwave heating method of this embodiment, it is possible to suppress harmful effects caused by excessive microwave irradiation while efficiently performing an annealing treatment on the film to be annealed 201 in a short time.

The present disclosure is not limited to the embodiments, and various modifications may be made. For example, the microwave heating apparatus of the present disclosure is not limited to a case where a semiconductor wafer is used as an object to be treated, but may be applied to, for example, a case where a substrate of a solar cell panel or a substrate for a flat panel display is used as an object to be treated.

The method of introducing the microwaves into the microwave heating apparatus, the number of microwave units 30 (the number of magnetrons 31), the number of microwave introduction ports 10, and the like are not limited to the forms described in the embodiments.

According to the microwave heating method and the microwave heating apparatus of the present disclosure in some embodiments, it is possible to suppress harmful effects caused by excessive microwave irradiation and to efficiently perform an annealing treatment on a film to be annealed in a short time.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A microwave heating method, comprising:
heating an object to be treated by irradiation of microwaves onto the object to be treated, the object to be treated having a film to be annealed and a substrate body on which the film to be annealed is formed; and
stopping the irradiation of the microwaves,
wherein the film to be annealed has a temperature rising rate by the irradiation of the microwaves higher than that of the substrate body, and
wherein switching from the heating the object to be treated to the stopping the irradiation of the microwaves is performed, after a temperature T₁ of the film to be annealed reaches a temperature equal to or greater than a target temperature T of the film to be annealed by the irradiation of the microwaves, and before a temperature T₂ of the substrate body reaches a steady state.

2. The microwave heating method of claim 1, wherein the switching from the heating the object to be treated to the stopping the irradiation of the microwaves is performed before or at a time when a difference T₁-T₂ between the temperature T₁ of the film to be annealed and the temperature T₂ of the substrate body reaches a maximum value.

3. The microwave heating method of claim 1, wherein a timing of the switching from the heating the object to be treated to the stopping the irradiation of the microwaves is determined based on predetermined temperature rising data of the film to be annealed and predetermined temperature rising data of the substrate body.

4. The microwave heating method of claim 1, wherein a timing of the switching from the heating the object to be treated to the stopping the irradiation of the microwaves is determined based on temperature measurement results of the substrate body and predetermined temperature rising data of the film to be annealed.

5. The microwave heating method of claim 3, wherein the temperature rising data of the film to be annealed are provided according to a film thickness of the film to be annealed.

6. The microwave heating method of claim 3, wherein the temperature rising data of the film to be annealed are provided according to a material of the film to be annealed.

7. The microwave heating method of claim 3, wherein the temperature rising data of the film to be annealed are provided according to a power of the microwaves.

8. The microwave heating method of claim 1, wherein the heating the object to be treated and the stopping the irradiation of microwaves are repeated plural times.

9. The microwave heating method of claim 1, wherein a material of the film to be annealed is metal.

10. A microwave heating apparatus, comprising:
a treatment container that has a microwave radiation space and accommodates an object to be treated;
a supporting device that supports the object to be treated in the treatment container;
a microwave introduction device that generates microwaves for heating the object to be treated and introduces the generated microwaves into the treatment container;
a temperature-measuring device that measures a temperature of the object to be treated; and
a control unit that controls irradiation of the microwaves onto the object to be treated,
wherein the object to be treated has a film to be annealed and a substrate body on which the film to be annealed is formed, and
wherein if the film to be annealed has a temperature rising rate by the irradiation of the microwaves higher than that of the substrate body, the control unit performs switching from heating the object to be treated by irradiation of the microwaves to stopping the irradiation of the microwaves, after a temperature T₁ of the film to be annealed reaches a temperature equal to or greater than a target temperature T of the film to be annealed by the irradiation of the microwaves, and before a temperature T₂ of the substrate body reaches a steady state.

11. The microwave heating apparatus of claim 10, wherein the control unit performs the switching from the heating the object to be treated to the stopping the irradiation of the microwaves before or at a time when a difference T₁−T₂ between the temperature T₁ of the film to be annealed and the temperature T₂ of the substrate body reaches a maximum value.

12. The microwave heating apparatus of claim 10, wherein the control unit determines a timing of the switching from the heating the object to be treated to the stopping the irradiating microwaves, based on predetermined temperature rising data of the film to be annealed and predetermined temperature rising data of the substrate body.

13. The microwave heating apparatus of claim 10, wherein the control unit determines a timing of the switching from the heating the object to be treated to the stopping the irradiation of the microwaves, based on temperature measurement results of the substrate body obtained by the temperature-measuring device and predetermined temperature rising data of the film to be annealed.

14. The microwave heating apparatus of claim 12, wherein the temperature rising data of the film to be annealed are provided according to a film thickness of the film to be annealed.

15. The microwave heating apparatus of claim 12, wherein the temperature rising data of the film to be annealed are provided according to a material of the film to be annealed.

16. The microwave heating apparatus of claim 12, wherein the temperature rising data of the film to be annealed are provided according to a power of the microwaves.

17. The microwave heating apparatus of claim 10, wherein the heating the object to be treated to the stopping the irradiation of the microwaves are repeated plural times.
